(19) United States
(12) Patent Application Publication
(10) Pub. No.: US 2022/0075223 A1
(43) Pub. Date: Mar. 10, 2022

(54) DISPLAY DEVICE

(71) Applicant: Japan Display Inc., Tokyo (JP)

(72) Inventors: Tomokazu ISHIKAWA, Tokyo (JP); Masashi SHISHIKURA, Tokyo (JP); Masaru NAKAKOMI, Tokyo (JP)

(73) Assignee: Japan Display Inc., Tokyo (JP)

(21) Appl. No.: 17/455,683

(22) Filed: Nov. 19, 2021

Related U.S. Application Data
(63) Continuation of application No. PCT/JP2020/020414, filed on May 22, 2020.

(30) Foreign Application Priority Data
May 24, 2019 (JP) 2019-097560

(51) Int. Cl. G02F 1/1339; G02F 1/1335

(52) U.S. Cl. CPC G02F 1/13392; G02F 1/133514; G02F 1/133512

(57) ABSTRACT

According to one embodiment, a display device includes a first substrate including a first area including a display area and a frame area, and a second area, a second substrate including a first end portion and a second end portion, and overlapping the first area, and a sealant that is located in the frame area. A width of the frame area between the first end portion and the display area is smaller than a width of the frame area between the second end portion and the display area. A width of the sealant between the first end portion and the display area is smaller than a width of the sealant between the second end portion and the display area.

### CROSS-REFERENCE TO RELATED APPLICATIONS

This application is a Continuation Application of PCT Application No. PCT/JP2020/020414, filed May 22, 2020 and based upon and claiming the benefit of priority from Japanese Patent Application No. 2019-097560, filed May 24, 2019, the entire contents of all of which are incorporated herein by reference.

### FIELD

Embodiments described herein relate generally to a display device.

### BACKGROUND

In recent years, a variety of display devices have been studied, in which the display devices comprise a TFT substrate on which pixels including pixel electrodes, thin-film transistors (TFTs), and the like are formed in a matrix and a counter-substrate that faces the TFT substrate, and liquid crystal molecules are rotated by an electric field in a direction parallel to the two substrates. In one example, a display device is disclosed in which an organic insulating layer has a groove-shaped through hole formed in a manner surrounding an area sandwiching a liquid crystal in an area where two substrates overlap.

### BRIEF DESCRIPTION OF THE DRAWINGS

FIG. 1 is a plan view of a liquid crystal display device of an embodiment.

FIG. 2 shows a basic configuration of a plurality of pixels and equivalent circuit of the pixel shown in FIG. 1.

FIG. 3 is a sectional view of a configuration example of a display panel shown in FIG. 1.

FIG. 4 is a plan view of a second substrate SUB2 shown in FIG. 1 for explaining a display area DA.

FIG. 5 is a plan view of the liquid crystal display device shown in FIG. 1 for explaining the positional relationship between a groove and line groups.

FIG. 6 is a plan view of the liquid crystal display device shown in FIG. 5 for explaining the positional relationship between the groove and recess portions.

FIG. 7 is a sectional view of a display panel taken along line A-B shown in FIG. 6.

FIG. 8 is a sectional view of the display panel taken along line C-D shown in FIG. 6.

FIG. 9 is a plan view for explaining a spacer of a modified example of the present embodiment.

### DETAILED DESCRIPTION

In general, according to one embodiment, there is provided a display device comprising: a first substrate comprising a first area including a display area and a frame area, and a second area adjacent to the first area; a second substrate comprising a first end portion located at a boundary between the first area and the second area and a second end portion different from the first end portion, and overlapping the first area; and a sealant that is located in the frame area and bonds the first substrate and the second substrate together. A width of the frame area between the first end portion and the display area is smaller than a width of the frame area between the second end portion and the display area. A width of the sealant between the first end portion and the display area is smaller than a width of the sealant between the second end portion and the display area.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

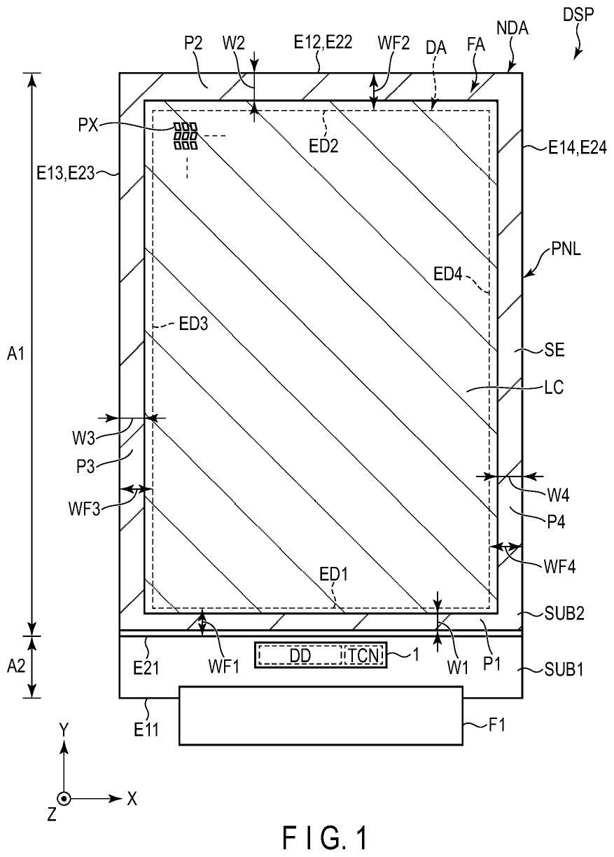

FIG. 1 is a plan view of a liquid crystal display device DSP according to an embodiment. For example, a first direction X, a second direction Y and a third direction Z are orthogonal to each other, but may intersect at an angle other than 90 degrees. The first direction X and the second direction Y correspond to directions parallel to a main surface of a substrate which constitutes the liquid crystal display device DSP, and the third direction Z corresponds to a thickness direction of the liquid crystal display device DSP. In the following descriptions, a direction forwarding a tip of an arrow indicating the third direction Z is referred to as “upward” and a direction forwarding oppositely from the tip of the arrow is referred to as “downward”. Supposing an observation position for observing the liquid crystal display DSP on a tip side of the arrow indicating the third direction Z, viewing from the observation position toward the X-Y plane defined by the first direction X and the second direction Y is referred to as “plan view”.

As shown in FIG. 1, the liquid crystal display device DSP comprises a display panel PNL, an IC chip 1, and a wiring substrate F1.

The display panel PNL includes a first substrate SUB1, a second substrate SUB2, a liquid crystal layer LC, and a sealant SE. In FIG. 1, the liquid crystal layer LC and the sealant SE are shown in different hatch lines. The display panel PNL has a first area A1 and a second area A2 arranged in the second direction Y.

The first substrate SUB1 includes end portions E11 and 512 extending in the first direction X, and end portions 513 and 514 extending in the second direction Y. The second substrate SUB2 includes end portions E21 and E22 extending in the first direction X and end portions E23 and E24 extending in the second direction Y. The end portion E21 corresponds to a substrate end located at the boundary between the first area A1 and the second area A2. In other words, the first area A1 corresponds to an area surrounded by the end portions E21, E12, E13, and E14. The second area A2 corresponds to an area surrounded by the end portions E11, E21, E13, and E14. It can also be considered that the first area A1 is a two-piece portion of the display panel PNL where the first substrate SUB1 and the second substrate SUB2 overlap, and the second area A2 is a one-piece portion of the display panel PNL where the first substrate SUB1 is exposed from the second substrate SUB2.

The first area A1 includes a display area DA for displaying images and a frame-shaped frame area FA surrounding the display area DA.

The display area DA is shown as a substantially quadrangle area; however, the four corners may be rounded, and the area may be a polygon or circle other than a quadrangle. It may also be one in which notches for cameras are formed at the end portions 512 and E22. The display area DA is located inside an area surrounded by the sealant SE. The display area DA has edges ED1 and ED2 extending in the first direction X, and edges ED3 and ED4 extending in the second direction Y. The edge ED1 is close to the end portion E21, the edge ED2 is close to the end portion E22, the edge ED3 is close to the end portion E23, and the edge ED4 is close to the end portion 524.

In the display area DA, there are a plurality of pixels PX arranged in matrix in the first direction (columnar direction) X and the second direction (row direction) Y. A pixel PX here indicates the smallest unit that can be individually controlled according to a pixel signal, and may be referred to as a sub-pixel. A pixel PX is, for example, a red pixel that exhibits red, a green pixel that exhibits green, a blue pixel that exhibits blue, or a white pixel that exhibits white.

The sealant SE is located in the frame area FA, bonds the first substrate SUB1 and the second substrate SUB2, and seals the liquid crystal layer LC. The sealant SE includes a first sealing portion P1 and a second sealing portion P2 extending in the first direction X, and a third sealing portion P3 and a fourth sealing portion P4 extending in the second direction Y. The first sealing portion P1 is located between the edge ED1 and the end portion E21 and has a substantially constant width W1. In the illustrated example, the first sealing portion P1 is separated from the end portion E21. The second sealing portion P2 overlaps with the end portion E22 and has a substantially constant width W2. The third sealing portion P3 overlaps with the end portion E23 and has a substantially constant width W3. The fourth sealing portion P4 overlaps with the end portion E24 and has a substantially constant width W4. Here, the widths W1 to W4 correspond to the lengths in a direction perpendicular to the direction in which the sealant SE extends. In the illustrated example, the width W1 is smaller than each of the widths W2 to W4. As an example, the width W1 is approximately 350 μm, and the widths W2 to W4 are approximately 400 μm each. Note that the width W1 may be equivalent to each of the widths W2 to W4.

Recently, display devices including liquid crystal display devices are required to have a narrower frame in which the width of the frame area FA is narrowed, and the width of the sealant SE is also narrowed as the frame area FA is narrowed. Furthermore, narrowing the frame is not limited to the upper frame and the left and right frames of the panel, and it is preferred that the lower frame is also narrowed to the same extent as the upper and left and right frames. In the present description, the panel upper frame is a frame area having a width WF2 including a panel upper edge including the end portion E12 of the first substrate SUB1 and the end portion E22 of the second substrate SUB2, and the edge ED2 of the display area DA. The panel left frame, in the present description, is a frame area having a width WF3 including a panel left edge including the end portion 513 of the first substrate SUB1 and the end portion E23 of the second substrate SUB2, and the edge ED3 of the display area DA. The panel right frame, in the present description, is a frame area having a width WF4 including a panel right edge including the end portion 514 of the first substrate SUB1 and the end portion E24 of the second substrate SUB2, and the edge ED4 of the display area DA. The panel lower frame, in the present description, is a frame area including the second area A2 of the first substrate SUB1, the end portion E11 of the first substrate SUB1 which is the lower edge of the panel itself, and further, the end portion E21 of the second substrate SUB2, and the edge ED1 of the display area DA. Here, the end portion E21 of the second substrate SUB2 and the edge ED1 of the display area DA may be referred to as a terminal edge side frame of the second substrate SUB2, and the terminal edge side frame of the second substrate SUB2 has a width WF1. Here, the width WF1 is smaller than each of the widths WF2 to WF4. In one example, each of the widths WF2 to WF4 is 0.7 to 1.0 mm, and the width WF1 is 0.4 to 0.69 mm. Considering the second area A2 of the first substrate SUB1, the smaller the width WF1 is, the more desirable it is for narrowing the top, bottom, left, and right frame areas of the panel. In the present example, since the IC chip 1 and the wiring substrate F1 are to be mounted, there is a restriction on narrowing the second area A2 of the first substrate SUB1. Therefore, the present example focuses on narrowing the width WF1 between the end portion E21 of the second substrate SUB2 and the edge ED1 of the display area.

The IC chip 1 and the wiring substrate F1 function mainly as signal sources that supply signals to the display panel PNL, although they may also read signals from the display panel PNL. These signal sources are mounted in the second area A2. In the illustrated example, the wiring substrate F1 and the IC chip 1 are mounted in the second area A2, respectively. The IC chip 1 may also be mounted on the wiring substrate F1. The IC chip 1 has a built-in display driver DD that outputs signals necessary for image display in the image display mode for displaying images. In the illustrated example, the IC chip 1 also has a built-in touch controller TCN that controls a touch sensing mode for detecting an object approaching or contacting the liquid crystal display device DSP. In the drawing, the display driver DD and the touch controller TCN are shown by dashed lines. The wiring substrate F1 is a flexible printed circuit that can be bent.

The display panel PNL in the present embodiment may be a transmissive display panel PNL with a transmissive display function that displays images by selectively transmitting light from the back side of the first substrate SUB1, a reflective display panel PNL with a reflective display function that displays images by selectively reflecting light from the front side of the second substrate SUB2, or a transreflective display panel PNL with the transmissive display function and the reflective display function.

The detailed configuration of the display panel PNL will not be described here; however, the display panel PNL may have any configuration corresponding to a display mode that uses a lateral electric field along the main surface of the substrate, a display mode that uses a longitudinal electric field along the normal of the main surface of the substrate, a display mode that uses an inclined electric field that is angled with respect to the main surface of the substrate, and, further, a display mode that uses a combination of the above lateral electric field, longitudinal electric field, and inclined electric field as appropriate. The main surface of the substrate here is a plane parallel to the X-Y plane defined by the first direction X and the second direction Y.

The display panel PNL is not limited to application to the liquid crystal display device DSP, and can also be applied to self-luminous display devices such as organic electro luminescence (EL) display devices and micro light emitting diode (LED) display devices, as long as it includes the first substrate SUB1, second substrate SUB2, and sealant SE. In an organic EL display device, for example, the sealant SE may be a resin seal used in a liquid crystal display device, such as a glass frit.

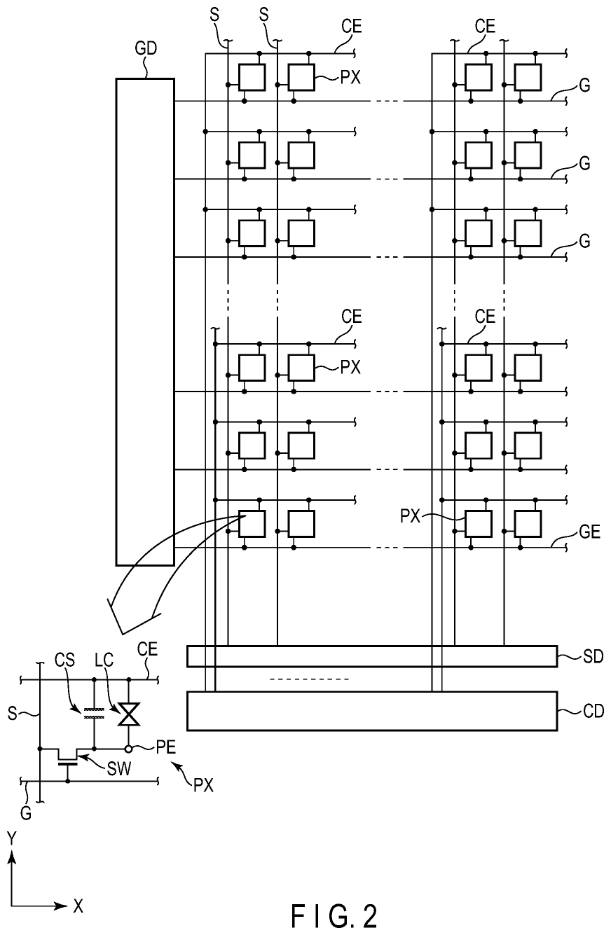

FIG. 2 shows a basic configuration of the pixels PX shown in FIG. 1 and equivalent circuit of the pixel.

As shown in FIG. 2, a plurality of scanning lines G are connected to a scanning line driving circuit GD, and a plurality of signal lines S are connected to a signal line driving circuit SD. A scanning line GE is a scanning line closest to the end portion E21 shown in FIG. 1 among the scanning lines G connected to the scanning line drive circuit GD. In the present embodiment, the scanning line GE is located at the boundary between the display area DA and the frame area FA, and extends along the edge ED1 of the display area DA.

The scanning line G and the signal line S are respectively formed of metal materials such as aluminum (Al), titanium (Ti), silver (Ag), molybdenum (Mo), tungsten (W), copper (Cu), and chromium (Cr), or alloys combining these metal materials. The scanning line G and the signal line S may be single-layered or multi-layered structures, respectively. The scanning line G and the signal line S do not necessarily have to extend in a straight line, and some of them may be bent.

A common electrode CE is disposed over a plurality of pixels PX. The common electrode CE is connected to a voltage supply CD and the touch controller TCN shown in FIG. 1. In the image display mode, the voltage supply unit CD supplies a common voltage (Vcom) to the common electrode CE. In the touch sensing mode, the touch controller TCN supplies a touch driving voltage different from the common voltage to the common electrode CE.

Each pixel PX includes a switching element SW, a pixel electrode PE, a common electrode CE, a liquid crystal layer LC, and etc. The switching element SW is configured by a TFT, for example, and is electrically connected to the scanning line G and the signal line S. The scanning line G is electrically connected to the switching element SW in each of the pixels PX arranged in the first direction X. The signal line S is electrically connected to the switching element SW in each of the pixels PX arranged in the second direction Y. The scanning line G is supplied with a control signal for controlling the switching element SW. A video signal is supplied to the signal line S as a signal different from the control signal. The pixel electrode PE is electrically connected to the switching element SW. The liquid crystal layer LC is driven by the electric field generated between the pixel electrode PE and the common electrode CE. A capacitance CS is formed, for example, between an electrode of the same potential as the common electrode CE and an electrode of the same potential as the pixel electrode PE.

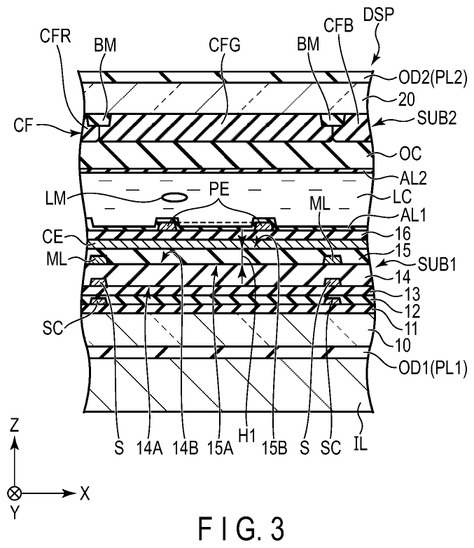

FIG. 3 is a sectional view showing a configuration example of the display panel PNL shown in FIG. 1. The illustrated example corresponds to an example in which a fringe field switching (FFS) mode, one of the display modes using a lateral electric field, is applied.

As shown in FIG. 3, the first substrate SUB1 includes an insulating substrate 10, insulating layers 11 to 16, a semiconductor layer SC, the signal line S, a metal line ML, the common electrode CE, the pixel electrode PE, an alignment film AL1, and etc. The insulating substrate 10 is a transparent substrate such as a glass substrate or a flexible resin substrate. The insulating layer 11 is located on the insulating substrate 10. The semiconductor layer SC is located on the insulating layer 11 and is covered by the insulating layer 12. The semiconductor layer SC is formed, for example, of polycrystalline silicon, but may also be formed of amorphous silicon or oxide semiconductor. The insulating layer 12 is covered by the insulating layer 13. The scanning line G shown in FIG. 2 is located between the insulating layers 12 and 13. The insulating layer 14 has a lower surface 14A and an upper surface 14B on the opposite side of the lower surface 14A. The insulating layer 15 has a lower surface 15A facing the upper surface 14B and an upper surface 15B on the opposite side of the lower surface 15A. The signal line S is located on the insulating layer 13 and is covered by the insulating layer 14. The metal line ML is located on the upper surface 14B and is covered by the insulating layer 15. The metal line ML is formed, for example, of metal materials such as aluminum (Al), titanium (Ti), silver (Ag), molybdenum (Mo), tungsten (W), copper (Cu), and chromium (Cr), or an alloy combining these metal materials. The metal line ML may be a single-layer structure or a multi-layer structure. Each metal line ML extends parallel to the signal line S and is located directly above the signal line S.

The common electrode CE is located on the upper surface 15B and is covered by the insulating layer 16. The pixel electrode PE is located on the insulating layer 16 and is covered by the alignment film AL1. Each of the pixel electrodes PE is facing the common electrode CE through the insulating layer 16. The common electrode CE and the pixel electrode PE are formed of transparent conductive materials, such as indium tin oxide (ITO) and indium zinc oxide (IZO). The pixel electrode PE is a linear electrode, and the common electrode CE is a flat plate electrode commonly provided across multiple pixels PX. It is also possible to have a structure in which the pixel electrode PE is a flat plate electrode, and a linear common electrode is provided between the pixel electrode PE and the liquid crystal layer LC.

The insulating layers 11, 12, 13, and 16 are inorganic insulating layers formed of inorganic insulating materials such as silicon oxide (SiO), silicon nitride (SiN), and silicon oxynitride (SiON). The insulating layer 16 is formed, for example, of silicon nitride. The insulating layers 11, 12, 13, and 16 may be single-layered or multi-layered structures. The insulating layers 14 and 15 are organic insulating layers formed of organic insulating materials such as acrylic resin. The upper surface 14B, the lower surface 15A, and upper surface 15B are respectively planarize. The insulating layer 15 has a thickness H1. The thickness H1 corresponds to the distance from the lower surface 15A to the upper surface 15B in the third direction Z. The thickness H1 is, for example, 1.5 μm.

The second substrate SUB2 includes an insulating substrate 20, a color filter CF, a light-shielding layer BM, a transparent layer OC, and an alignment film AL2. The insulating substrate 20 is a transparent substrate such as a glass substrate or a flexible resin substrate. The color filter CF, the light-shielding layer BM, and the transparent layer OC are located between the insulating substrate 20 and the liquid crystal layer LC. The alignment film AL2 is in contact with the liquid crystal layer LC. The alignment films AL1 and AL2 are formed, for example, of a material that exhibits horizontal alignment properties. The transparent layer OC covers the color filter CF and the light-shielding layer BM. The transparent layer OC is, for example, a transparent organic insulating layer. In the illustrated example, the color filter CF is provided on the second substrate SUB2, but it may also be provided on the first substrate SUB1. The color filter CF includes a red colored filter CFR, a green colored filter CFG, and a blue colored filter CFB. The green colored filter CFG faces the pixel electrode PE. The red colored filter CFR and the blue colored filter CFB also face other pixel electrodes PE that are not shown.

The liquid crystal layer LC is located between the first substrate SUB1 and the second substrate SUB2, and is held between the alignment film AL1 and the alignment film AL2. The liquid crystal layer LC includes liquid crystal molecules LM. The liquid crystal layer LC is configured by a positive type (positive dielectric constant anisotropy) liquid crystal material or a negative type (negative dielectric constant anisotropy) liquid crystal material.

In such a display panel PNL, in an OFF state where no electric field is formed between the pixel electrode PE and the common electrode CE, the liquid crystal molecules LM are initially aligned in a predetermined direction between the alignment films AL1 and AL2. In such an OFF state, illumination light emitted from an illumination device IL to the display panel PNL is absorbed by optical elements OD1 and OD2, resulting in a dark display. On the other hand, in an ON state where an electric field is formed between the pixel electrode PE and the common electrode CE, the liquid crystal molecules LM are aligned in a direction different from the initial alignment direction by the electric field, and the alignment direction is controlled by the electric field. In such an ON state, a part of the illumination light from the illumination device IL is transmitted through the optical elements OD1 and OD2, resulting in a bright display.

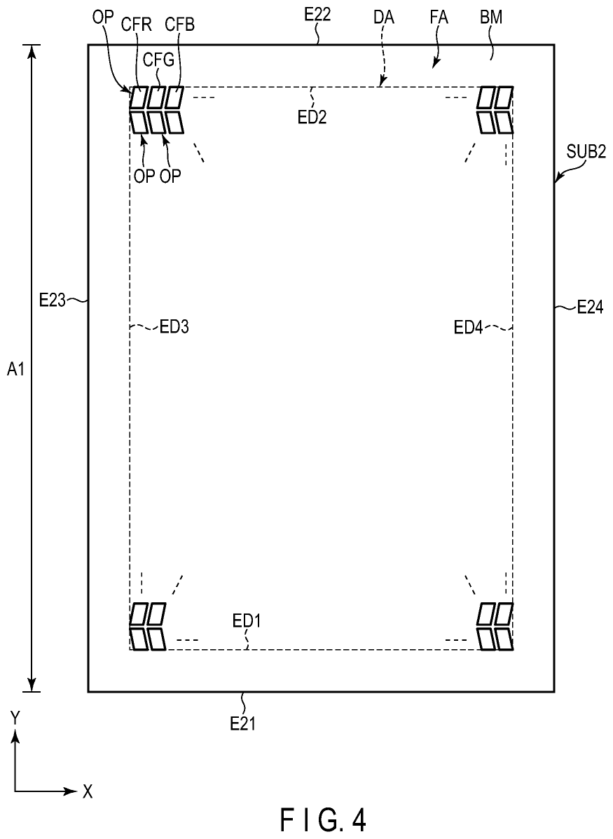

FIG. 4 is a plan view of the second substrate SUB2 shown in FIG. 1 for explaining the display area DA.

As shown in FIG. 4, the light-shielding layer BM extends to each of the end portions E21 to E24 and is provided in the entire first area A1. The light-shielding layer BM has a plurality of openings OP. Each opening OP corresponds to each pixel PX shown in FIG. 2 and FIG. 3, respectively. For example, the red colored filter CFR, the green colored filter CFG, and the blue colored filter CFB, which are the units configuring one pixel in the first direction X, are arranged in each opening OP in order. The edge ED1 is located on the same line as the outermost edge of the plurality of openings OP near the end portion E21, and the edge ED2 is located on the same line as the outermost edge of the plurality of openings OP near the end portion E22. The display area DA can also be referred to as an area including the plurality of openings OP of the light-shielding layer BM.

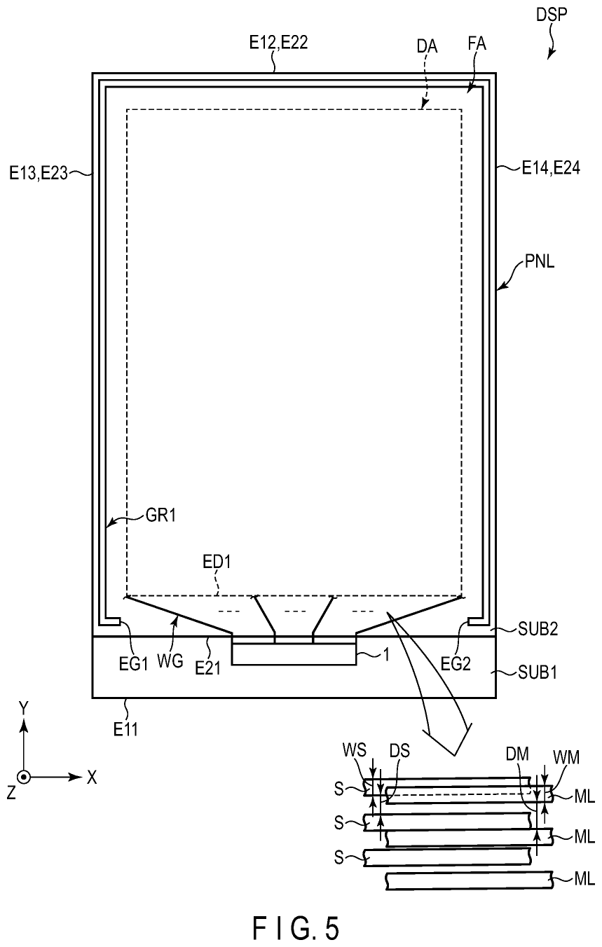

FIG. 5 is a plan view of the liquid crystal display device DSP shown in FIG. 1 for explaining the positional relationship between a groove GR1 and a line group WG.

As shown in FIG. 5, the display panel PNL includes the groove GR1 and the line group WG.

The groove GR1 is provided in the frame area FA and extends along each of the end portions E22 to E24. The groove GR1 includes end portions EG1 and EG2. The end portions EG1 and EG2 are located between the end portion E21 and the edge ED1.

The line group WG includes a plurality of signal lines S and a plurality of metal lines ML shown in FIG. 3, and is connected to the IC chip 1. The line group WG is located between the end portion EG1 and the end portion EG2.

As shown enlarged in FIG. 5, the plurality of signal lines S are arranged with intervals DS in directions intersecting the first direction X and the second direction Y. The signal lines S are formed in strips having a substantially constant width WS and extend along the directions intersecting the first direction X and the second direction Y. Here, the interval DS and the width WS correspond to a length in a direction perpendicular to the direction in which the signal line S extends. As an example, the interval DS is 2.5 μm, and the width WS is 2.0 μm.

The plurality of metal lines ML are arranged with intervals DM in directions intersecting the first direction X and the second direction Y. The metal lines ML are formed in strips having a substantially constant width WM and extend along the directions intersecting the first direction X and the second direction Y. Here, the interval DM and the width WM correspond to a length in a direction perpendicular to the direction in which the metal line ML extends. As an example, the interval DM is 3.5 μm, and the width WM is 2.0 μm.

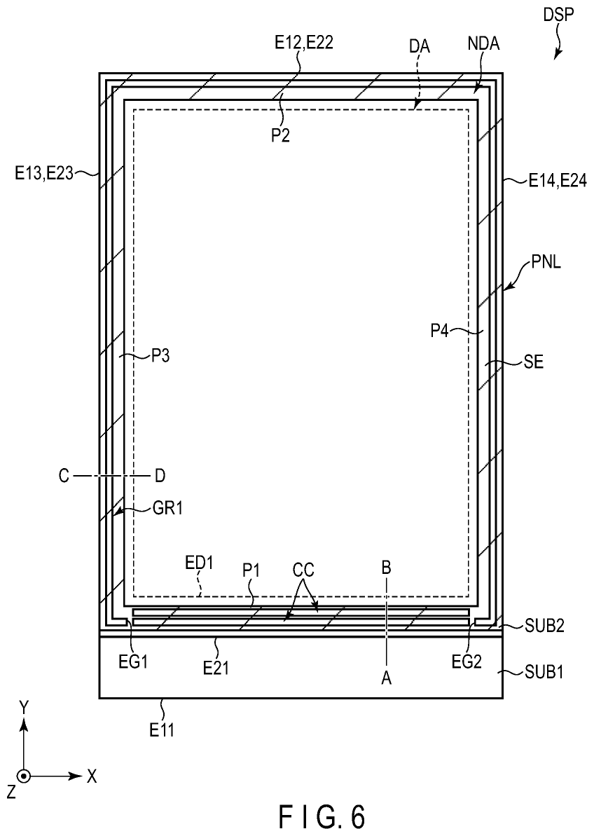

FIG. 6 is a plan view of the liquid crystal display device DSP shown in FIG. 5 for explaining the positional relationship between the groove GR1 and recess portions CC. The sealant SE is shown in hatch lines.

As shown in FIG. 6, the display panel PNL has a plurality of recess portions CC. The recess portions CC are located between the end portion EG1 and the end portion EG2 in the first direction X, and between the edge ED1 and the end portion E21 in the second direction Y. Each recess portion CC overlaps with the first sealing portion P1 of the sealant SE in plan view and is located inside the first sealing portion P1, respectively. In the illustrated example, two recess portions CC are provided apart from each other; however, one recess portion CC may be provided. The groove GR1 overlaps with each of the second to fourth sealing portions P2 to P4 in plan view.

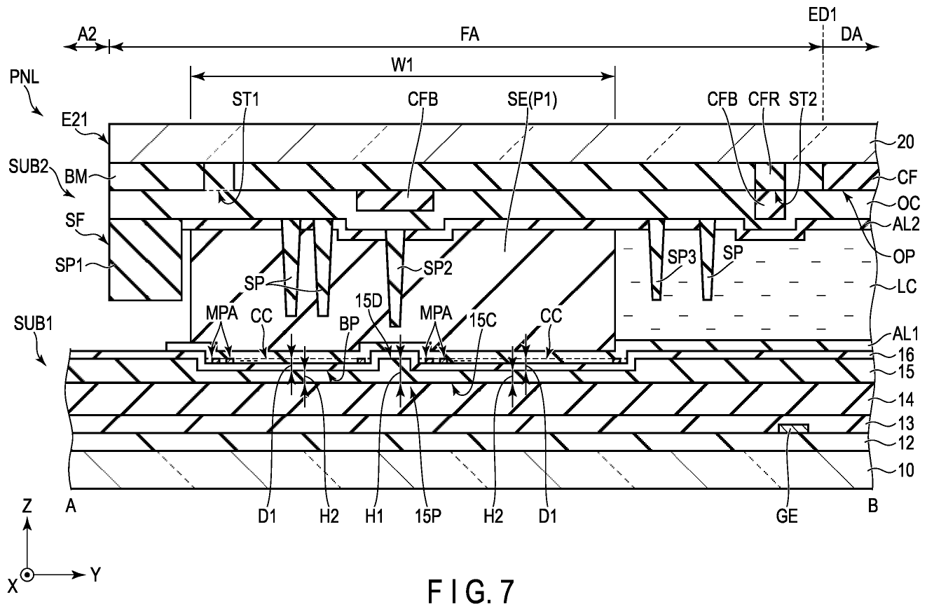

FIG. 7 is a sectional view of the display panel PNL taken along line A-B shown in FIG. 6. In FIG. 7, the signal line S and the metal line ML are omitted from the drawing.

As shown in FIG. 7, the insulating layer 15 includes a first portion 15P. The first portion 15P is located between the end portion E21 and the edge ED1 of the display area DA, and overlaps with the first sealing portion P1 of the sealant SE. The first portion 15P includes a main surface 15C, a main surface 15D, and a plurality of recess portions CC. The main surface 15C corresponds to the lower surface 15A shown in FIG. 3, and the main surface 15D corresponds to the upper surface 15B shown in FIG. 3. Each of the recess portions CC faces the sealant SE, is opened in the main surface 15D, and is depressed from the second substrate SUB2 to the first substrate SUB1 in the third direction Z. The recess portion CC has a bottom surface BP. The bottom surface BP is located between the main surface 15C and the main surface 15D in the third direction Z. The insulating layer 15 has a thickness H2 in an area where the bottom surface BP exists. The thickness H2 corresponds to the distance from the main surface 15C to the bottom surface BP in the third direction Z. The thickness H2 is, for example, 1.0 μm. A depth D1 of the recess portion CC is 0.5 μm. The depth D1 corresponds to the distance from the bottom surface BP to the main surface 15D in the third direction Z. In the illustrated example, the depth D1 is approximately 33.3% of the thickness H1. The depth D1 is in a range between 20% and 50% of the thickness H1, and preferably 50% of the thickness H1. In other words, the distance from the main surface 15C to the bottom surface BP is within a range of 50% or more and 80% or less of the distance from the main surface 15C to the main surface 15D.

The first substrate SUB1 further comprises a plurality of transparent conductive layers MPA. The transparent conductive layer MPA is formed of a transparent conductive material such as ITO or IZO. The transparent conductive layer MPA is formed above the insulating layer 16 at a position overlapping the first portion 15P, and is covered by an alignment film AL1. The transparent conductive layer MPA is in contact with each of the insulating layer 16 and the alignment film AL1. In the illustrated example, the transparent conductive layer MPA is not formed above the main surface 15C, however, may be formed above the main surface 15C. The transparent conductive layers MPA are arranged at intervals and are electrically floating state. Since the adhesive strength between the transparent conductive layer MPA and the alignment film AL1 is stronger than that between the insulating layer 15 and the alignment film AL1, the alignment film AL1 can be suppressed from the possibility of peeling off from the insulating layer 16 due to stress caused by adhesion with the first sealing portion P1 of the sealant SE.

The light-shielding layer BM has a slit ST1 that penetrates up to the insulating substrate 20. By forming the slit ST1, it is possible to prevent moisture from entering the display area DA from the outside through the light-shielding layer BM. In addition, the light-shielding layer BM has a slit ST2 in an area where it overlaps with the liquid crystal layer LC. By forming the slit ST2, the transfer of electric charge to the display area DA through the light-shielding layer BM can be blocked. Thereby, in the manufacturing process of the display panel PNL, it is possible to suppress the concentration of static electricity on the display area DA and suppress the display panel PNL from being damaged. In addition, the red colored filter CFR and the blue colored filter CFB are superposed in the third direction Z in the slit ST2. Therefore, it possible to suppress light leakage from the slit ST2.

A plurality of spacers SP (SP1, SP2, . . . ) are located between the first substrate SUB1 and the second substrate SUB2, and protrude from the lower surface of the transparent layer OC toward the first substrate SUB1. The spacer SP is formed of a resin material.

The spacer SP1 includes a side surface SF that is continuous with the end portion E21. In the illustrated example, the spacer SP1 is provided on the lower surface of the transparent layer OC, is located between the second substrate SUB2 and the insulating layer 15, and is not in contact with the sealant SE. The spacer SP1 may also be in contact with the sealant SE. The sealant SE is located between the side surface SF and the display area DA. The spacer SP1 is used to suppress the sealant SE from extending to the second area A2 side from the end portion E21 when the first substrate SUB1 and the second substrate SUB2 are bonded by the sealant SE.

The spacer SP2 faces the color filter CFB, is located between the main surface 15C and the transparent layer OC, and extends along the end portion E21 in the first direction X. The spacer SP2 is used to maintain a cell gap between the first substrate SUB1 and the second substrate SUB2.

The spacer SP3 is located between the first sealing portion P1 of the sealant SE and the edge ED1 of the display area DA. In the illustrated example, the spacer SP3 is not in contact with the sealant SE, but may be in contact with it. The spacer SP3 is used to suppress the sealant SE from spreading to the display area DA side when the first substrate SUB1 and the second substrate SUB2 are bonded by the sealant SE.

According to the present embodiment, the organic insulating layer 15 has a recess portion CC depressed from the second substrate SUB2 toward the first substrate SUB1 between the edge ED1 of the display area DA and the end portion E21. Compared to a case in which the organic insulating layer 15 does not have the recess portion CC, the volume of the sealant SE that can be accepted in the frame area FA can be increased. As a result, the width W1 of the sealant SE can be made narrower in the frame area FA, and the display panel PNL can be made narrower. In addition, when applying the sealant SE by, for example, a dispenser, since the sealant SE flows into the recess portion CC, it is possible to suppress the spreading of the sealant SE to the second area A2 or the display area DA. Therefore, contact failure of the IC chip 1 caused by the sealant SE covering the terminals of the IC chip 1 and display failure of the display panel PNL caused by the sealant SE extending into the display area DA can be suppressed, thereby allowing the product yield of the liquid crystal display device DSP to improve.

The larger the depth D1 of the recess CC, the larger the volume of the sealant SE that can be accepted is. However, if the thickness H2 becomes too small, the recess portion CC may penetrate the insulating layer 15. Furthermore, if the depth D1 of the recess portion CC is too small, the volume of the sealant SE that can be accepted cannot be increased much, and the width W1 of the sealant SE cannot be reduced. According to the present embodiment, the distance from the main surface 15C to the bottom surface BP of the recess portion CC (thickness H2) is 50% or more and 80% or less of the distance from the main surface 15C to the main surface 15D (thickness H1). The depth D1 of the recess portion CC is between 20% and 50% of the thickness H1. This allows to suppress the decrease in the product yield described above.

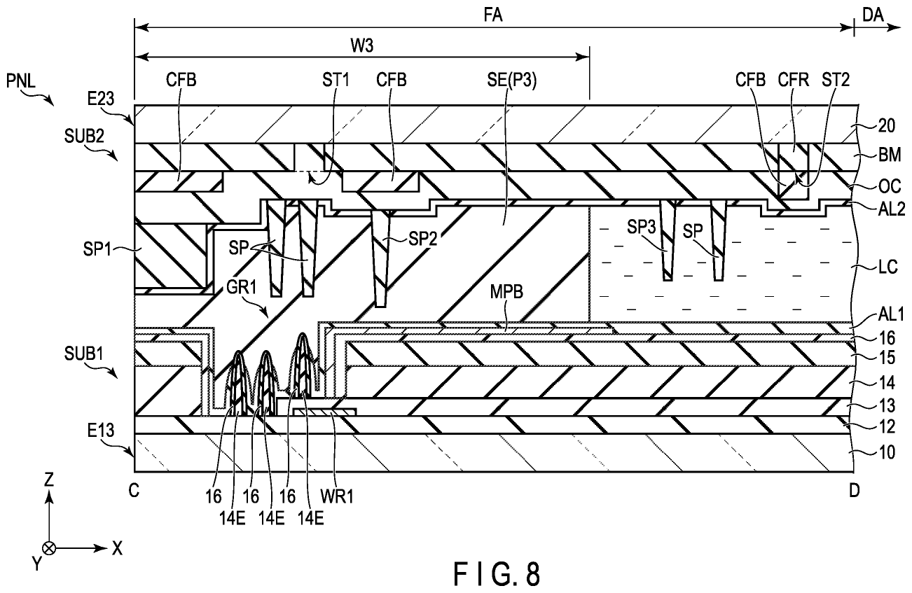

FIG. 8 is a sectional view of the display panel PNL taken along line C-D shown in FIG. 6.

As shown in FIG. 8, the first substrate SUB1 further includes a metal line WR1 and a transparent conductive layer MPB. The metal line WR1 is located above the insulating layer 12 and is covered by the insulating layer 13. Since the metal line WR1 is located directly below the slit ST1, light leakage from the slit ST1 can be suppressed. In addition, since the metal line WR1 is closer to the end portion E13 than the various types of wiring, it functions as a guard ring to prevent static electricity and external electric fields from acting on the display area DA.

The groove GR1 penetrates each of the insulating layers 14 and 15. The insulating layer 14 has a plurality of protruding portions 14E in the groove GR1. The protruding portions 14E are formed in a shape that tapers toward the second substrate SUB2 and are covered by the insulating layer 16. Therefore, even if the alignment film AL1 is applied to the first substrate SUB1 during manufacturing, the alignment film AL1 does not remain in the area located directly above the upper end of the protruding portions 14E, thus exposing the insulating layer 16 from alignment film AL1. When the first substrate SUB1 and the second substrate SUB2 are bonded together, the insulating layer 16 located at the upper edge of the protruding portion 14E is directly adhered to the sealant SE. Since the adhesive force between the sealant SE and the insulating layer 16 is stronger than the adhesive force between the sealant SE and the alignment film AL1, the liquid crystal display device DSP can form an adhesive area with sufficient adhesive strength.

The transparent conductive layer MPB is located on the insulating layer 16 and is covered by the alignment film AL1. Since the adhesive strength between the transparent conductive layer MPB and the alignment film AL1 is stronger than that between the insulating layer 15 and the alignment film AL1, the alignment film AL1 can be suppressed from the possibility of peeling off from the insulating layer 16 due to stress caused by adhesion with the third sealing portion P3 of the sealant SE.

Here, the peripheral structure of the third sealing portion P3 of the sealant SE has been described; however, the same applies to the peripheral structures of the second sealing portion P2 and the fourth sealing portion P4.

In the above configuration example, the end portion E21 corresponds to a first end portion, the end portions E22 to E24 correspond to second end portions, the metal line ML corresponds to a metal line, the insulating layer 14 corresponds to a first organic insulating layer, the insulating layer 15 corresponds to a second organic insulating layer, the main surface 15D corresponds to a first main surface, the main surface 15C corresponds to a second main surface, the spacer SP1 corresponds to a first spacer, the spacer SP3 corresponds to a second spacer, and the spacer SP2 corresponds to a third spacer.

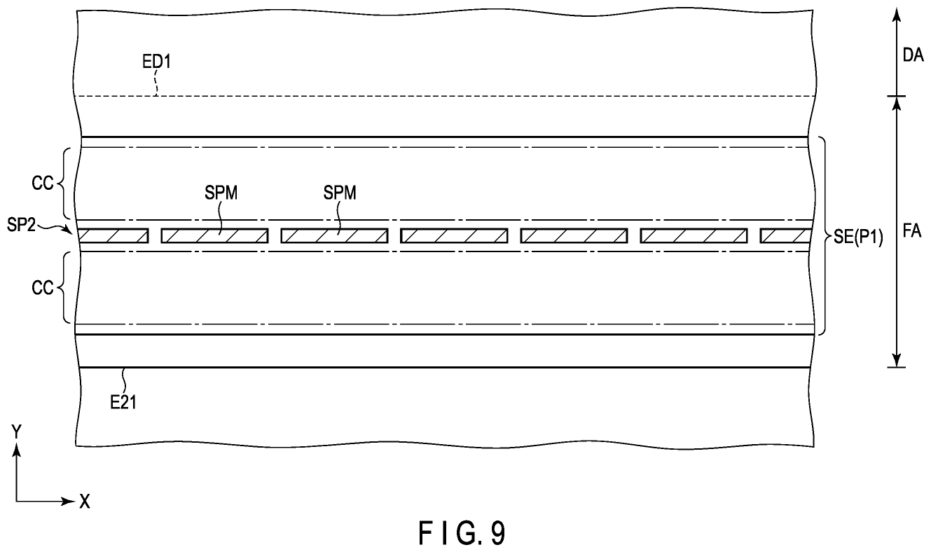

FIG. 9 is a plan view to illustrate the spacer SP2 of a modified example of the present embodiment. The recess portion CC is shown by a one dot chain line.

As shown in FIG. 9, the modified example of the present embodiment differs from the present embodiment in that the spacer SP2 is configured by a plurality of spacers SPM that are intermittently extended and arranged at intervals.

In such a modified example, the same effect as in the present embodiment described above can be obtained. In addition, since the sealant SE can be extended between adjacent spacers SPM, the volume of the sealant SE that can be accepted between the edge ED1 and the end portion E21 can be further increased.

As explained above, the present embodiment can provide a display device that enables narrow framing and further improves product yield.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a first substrate comprising a first area including a display area and a frame area, and a second area adjacent to the first area;
a second substrate comprising a first end portion located at a boundary between the first area and the second area and a second end portion different from the first end portion, and overlapping the first area; and
a sealant that is located in the frame area and bonds the first substrate and the second substrate together,
wherein
a width of the frame area between the first end portion and the display area is smaller than a width of the frame area between the second end portion and the display area, and
a width of the sealant between the first end portion and the display area is smaller than a width of the sealant between the second end portion and the display area.

2. The display device of claim 1, further comprising
a liquid crystal layer located between the first substrate and the second substrate,
wherein
the sealant seals the liquid crystal layer,
the first substrate comprises a first organic insulating layer including a flat upper surface facing the second substrate, a metal line formed above the upper surface, and a second organic insulating layer located above the metal line and the first organic insulating layer,
the second organic insulating layer includes a first portion that is located between the display area and the first end portion and overlaps the sealant, and
the first portion includes a flat first main surface, and a recess portion that opens in the first main surface, is depressed from the second substrate toward the first substrate, and faces the sealant.

3. The display device of claim 2, wherein
the first portion includes a second main surface on an opposite side of the first main surface, and
a distance from the second main surface to a bottom surface of the recess portion is 50% or more and 80% or less of a distance from the second main surface to the first main surface.

4. The display device of claim 3, further comprising
a first spacer including a side surface that is continuous with the first end portion and is located between the second substrate and the second organic insulating layer,
wherein
the sealant is located between the side surface and the display area.

5. The display device of claim 4, further comprising
a second spacer located between the first substrate and the second substrate,
wherein
the sealant includes a first sealing portion facing the display area at a position overlapping the first portion, and
the second spacer is located between the first sealing portion and the display area.

6. The display device of claim 2, wherein
the first substrate further comprises an inorganic insulating layer formed above the first portion, a transparent conductive layer formed above the inorganic insulating layer and overlapping the first portion, and an alignment film covering the transparent conductive layer and adhered to the sealant, and
the transparent conductive layer is in contact with each of the inorganic insulating layer and the alignment film and is in an electrically floating state.

7. The display device of claim 6, further comprising
a third spacer located between the first substrate and the second substrate,
wherein
the second substrate comprises a light-shielding layer, a transparent layer covering the light-shielding layer, and a color filter located between the light-shielding layer and the transparent layer and facing the first main surface, and
the third spacer faces the color filter, is located between the transparent layer and the first main surface, and extends along the first end portion.

8. The display device of claim 7, wherein
the third spacer is configured by a plurality of spacers that are intermittently extended and arranged at intervals.
